(19) United States
(12) Patent Application Publication
(10) Pub. No.: US 2023/0204305 A1
(43) Pub. Date: Jun. 29, 2023

(54) HEAT DISSIPATION MEMBER AND COOLING DEVICE

(71) Applicant: Nidec Corporation, Kyoto (JP)

(72) Inventors: Yuta HORI, Kyoto (JP); Kazuhiro NISHIKAWA, Kyoto (JP); Koji MURAKAMI, Kyoto (JP); Kengo INOUE, Kyoto (JP); Yuki YANAGITA, Kyoto (JP)

(21) Appl. No.: 18/083,615

(22) Filed: Dec. 19, 2022

(30) Foreign Application Priority Data
Dec. 27, 2021 (JP) 2021-213022

(51) Int. Cl. F28F 3/02; F28D 21/00

(52) U.S. Cl. CPC F28F 3/02; F28D 21/00; F28D 2021/0019

(57) ABSTRACT

A heat dissipator includes a first top plate at one side end of a third direction at a first fin(s). A second top plate is at one side end of a third direction at a second fin(s). The second fin(s) includes an opening open to one side in the third direction and located on the other side in the first direction relative to the second top plate. A liquid-cooled jacket includes a top surface that can oppose the first top plate and the second top plate in the third direction. A first gap between the top surface and the first top plate and a second gap between the top surface and the second top plate are narrower toward one side in the first direction.

### CROSS-REFERENCE TO RELATED APPLICATIONS

The present application claims priority under 35 U.S.C. § 119 to Japanese Patent Application No. 2021-213022, filed on Dec. 27, 2021, the entire contents of which are hereby incorporated herein by reference.

### 1. FIELD OF THE INVENTION

The present disclosure relates to a heat dissipator and a cooling device.

### 2. BACKGROUND

Conventionally, a heat dissipator is used for cooling a heating element. The heat dissipator includes a base portion and a plurality of fins. The plurality of fins protrudes from the base portion. When a refrigerant such as water flows between adjacent fins in the plurality of fins, heat of the heating element moves to the refrigerant.

A conventional heat dissipator has a problem of improving cooling performance and suppressing pressure loss. When the pressure loss increases, a desired flow rate is not secured depending on the performance of the pump for circulating the refrigerant in some cases. Alternatively, it is necessary to employ a large, expensive pump in order to secure a desired flow rate.

### SUMMARY

An example embodiment of a heat dissipator of the present disclosure is a heat dissipator that can be installed in a liquid-cooled jacket, the heat dissipator including a plate-shaped base expanding in a first direction along a refrigerant flow direction and in a second direction orthogonal to the first direction, and having a thickness in a third direction orthogonal to the first direction and the second direction, a first fin group including first fins arranged in the second direction and protruding from the base to one side in the third direction, and a second fin group including second fins arranged in the second direction and protruding from the base to the one side in the third direction, at least one of the second fins being located on one side in the first direction that is a downstream side of the first fin group. A first top plate is provided at a third direction one side end of at least any of the first fins. A second top plate is provided at a third direction one side end of at least any of the second fins. The at least any of the second fins includes an opening that is open to one side in the third direction and is located on another side in the first direction relative to the second top plate. The liquid-cooled jacket includes a top surface that is able to oppose the first top plate and the second top plate in the third direction. A first gap between the top surface and the first top plate and a second gap between the top surface and the second top plate are narrower toward one side in the first direction.

The above and other elements, features, steps, characteristics and advantages of the present disclosure will become more apparent from the following detailed description of the example embodiments with reference to the attached drawings.

### BRIEF DESCRIPTION OF THE DRAWINGS

FIG. 1 is a sectional perspective view of a cooling device according to an example embodiment of the present disclosure.

FIG. 2 is a perspective view of a heat dissipator according to an example embodiment of the present disclosure.

FIG. 3 is a side view of a heat dissipator according to an example embodiment of the present disclosure as viewed to one side in the second direction.

FIG. 4 is a plan view of a heat dissipator according to an example embodiment of the present disclosure as viewed from one side in the third direction.

FIG. 5 is a perspective view of a first fin plate.

FIG. 6 is a perspective view of a second fin plate.

FIG. 7 is an enlarged perspective view illustrating a configuration of a first spoiler.

FIG. 8 is an enlarged perspective view illustrating a configuration of the first spoiler.

FIG. 9 is an enlarged perspective view illustrating a configuration of a second spoiler.

FIG. 10 is a view illustrating a portion of a flow of a refrigerant in a side view of a heat dissipator according to an example embodiment of the present disclosure as viewed to one side in the second direction.

FIG. 11 is a partially enlarged view illustrating a configuration in the vicinity between an upstream side fin group and a center fin group.

FIG. 12 is a side view of a heat dissipator according to a first modification of an example embodiment of the present disclosure as viewed to one side in the second direction.

FIG. 13 is a side view of a heat dissipator according to a second modification of an example embodiment of the present disclosure as viewed to one side in the second direction.

FIG. 14 is a side view of a heat dissipator according to a third modification of an example embodiment of the present disclosure as viewed to one side in the second direction.

FIG. 15 is a side view of a heat dissipator according to a fourth modification of an example embodiment of the present disclosure as viewed to one side in the second direction.

FIG. 16 is a side view of a heat dissipator according to a fifth modification of an example embodiment of the present disclosure as viewed to one side in the second direction.

### DETAILED DESCRIPTION

Hereinafter, example embodiments of the present disclosure will be described with reference to the drawings.

In the drawings, the first direction is defined as an X direction, X1 indicates one side in the first direction, and X2 indicates the other side in the first direction. The first direction is along a direction F in which a refrigerant W flows, and the downstream side is indicated by F1 and the upstream side is indicated by F2. The second direction orthogonal to the first direction is defined as a Y direction, Y1 indicates one side in the second direction, and Y2 indicates the other side in the side in the second direction. The third direction orthogonal to the first direction and the second direction is defined as a Z direction, Z1 indicates one side in the third direction, and Z2 indicates the other side in the third direction. The above-described orthogonal also includes intersection at an angle slightly shifted from 90 degrees. The above-described directions do not limit directions when a cooling device 110 and a heat dissipator 1 are incorporated in various types of equipment.

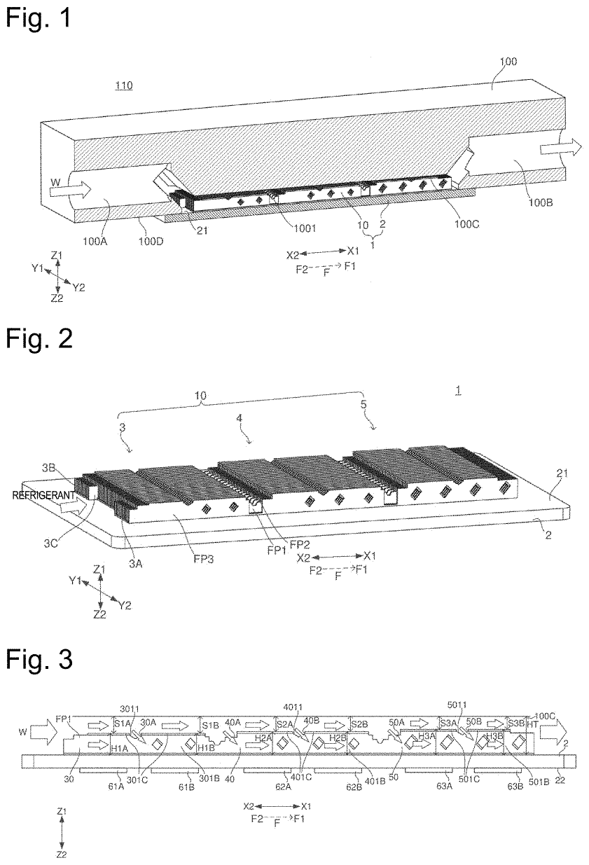

FIG. 1 is a sectional perspective view of the cooling device 110 according to an example embodiment of the present disclosure. The cooling device 110 includes the heat dissipator 1 and a liquid-cooled jacket 100 that houses the heat dissipator 1. FIG. 1 illustrates the flow of the refrigerant W. One side in the first direction is a downstream side in a direction in which the refrigerant W flows, and the other side in the first direction is an upstream side in the direction in which the refrigerant W flows. The refrigerant W is liquid such as water.

The heat dissipator 1 includes a heat dissipation fin part 10 and a base portion 2. The heat dissipation fin part 10 is fixed to one side in the third direction with respect to the base portion 2. The liquid-cooled jacket 100 includes an inlet flow path 100A disposed on the other side in the first direction and an outlet flow path 100B disposed on one side in the first direction. The liquid-cooled jacket 100 includes a top surface 100C disposed between the inlet flow path 100A and the outlet flow path 100B in the first direction.

In a state where the heat dissipator 1 is not attached to the liquid-cooled jacket 100, the top surface 100C is exposed to the other side in the third direction. The heat dissipator 1 is attached to the liquid-cooled jacket 100 by fixing one side surface 21 in the third direction of the base portion 2 in the heat dissipator 1 to the other side surface 100D in the third direction of the liquid-cooled jacket 100. In a state where the heat dissipator 1 is attached, the other side in the third direction of the top surface 100C is covered with the base portion 2, and a heat dissipation flow path 1001 is formed between the base portion 2 and the top surface 100C. The heat dissipation fin part 10 is disposed inside the heat dissipation flow path 1001. The inlet flow path 100A, the heat dissipation flow path 1001, and the outlet flow path 100B are coupled in the first direction.

The refrigerant W flowing from the outside of the liquid-cooled jacket 100 into the inlet flow path 100A flows inside the inlet flow path 100A to one side in the first direction and flows into the heat dissipation flow path 1001. The refrigerant W flowing through the heat dissipation flow path 1001 to one side in the first direction flows into the outlet flow path 100B and is discharged from the outlet flow path 100B to the outside of the liquid-cooled jacket 100. A heating element not illustrated is disposed on the other side in the third direction of the base portion 2, and the heat generated from the heating element moves from the heat dissipation fin part 10 to the refrigerant W flowing inside the heat dissipation flow path 1001, whereby the heating element is cooled.

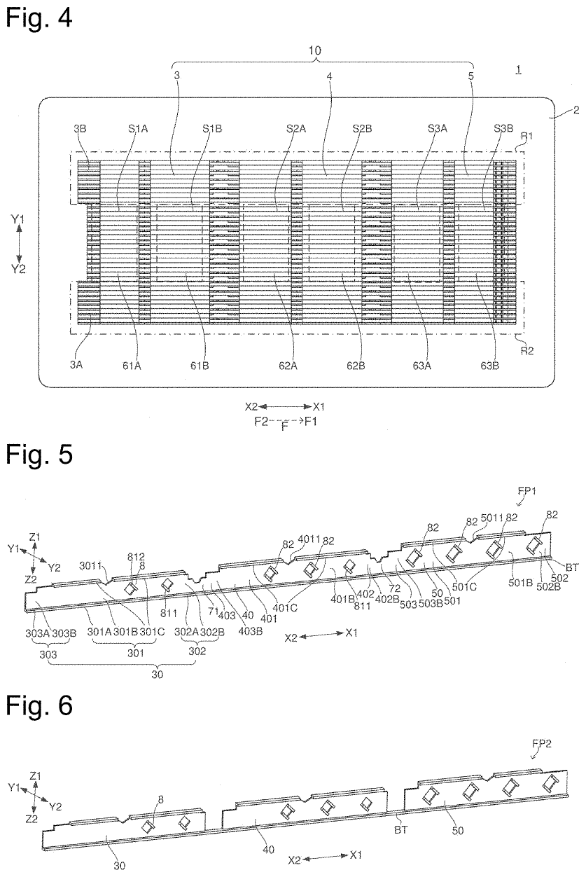

Next, the heat dissipator 1 will be described in more detail. FIG. 2 is a perspective view of the heat dissipator 1 according to an example embodiment of the present disclosure. FIG. 3 is a side view of the heat dissipator 1 as viewed to one side in the second direction. FIG. 4 is a plan view of the heat dissipator 1 as viewed from one side in the third direction. However, for convenience, FIG. 3 is a view in a state where a third fin plate FP3 (FIG. 1) positioned on the other side in the second direction is removed. Thus, FIG. 3 illustrates a first fin plate FP1. Details of the fin plate will be described later.

The heat dissipator 1 is a device that cools a plurality of heating elements 61A, 61B, 62A, 62B, 63A, and 63B (see FIGS. 3 and 4) arranged in the first direction. The heating elements 61A, 61B, 62A, 62B, 63A, and 63B (hereinafter, 61A and the like) are, for example, power transistors of an inverter provided in a traction motor for driving wheels of a vehicle. The power transistor is, for example, an insulated gate bipolar transistor (IGBT). In this case, the heat dissipator 1 is mounted on the traction motor. The number of heating elements may be a plurality other than six, or may be singular.

As described above, the heat dissipator 1 can be installed in the liquid-cooled jacket 100, and includes the base portion 2 and the heat dissipation fin part 10. The heat dissipation fin part 10 includes an upstream side fin group 3, a center fin group 4, and a downstream side fin group 5.

The base portion 2 has a plate shape extending in the first direction and the second direction and having a thickness in the third direction. The base portion 2 is made of a metal having high thermal conductivity, for example, a copper plate.

The upstream side fin group 3, the center fin group 4, and the downstream side fin group 5 are arranged on one side in the third direction of the base portion 2 from the other side (upstream side) in the first direction toward one side (downstream side) in the first direction in this order. As described later, the fin groups 3, 4, and 5 are fixed to the one side surface 21 in the third direction of the base portion 2 by brazing, for example.

The heating element 61A and the like are in direct or indirect contact with an other side surface 22 in the third direction of the base portion 2 (see FIG. 3). When viewed in the third direction, the heating elements 61A and 61B overlap the upstream side fin group 3, the heating elements 62A and 62B overlap the center fin group 4, and the heating elements 63A and 63B overlap the downstream side fin group 5 (see FIG. 4).

When the refrigerant W is supplied to the upstream side fin group 3 from the upstream side relative to the upstream side fin group 3, the refrigerant W sequentially flows through the fin groups 3, 4, and 5 and is discharged from the downstream side fin group 5 to the downstream side. At this time, the heat generated from the heating element 61A and the like moves to the refrigerant W via the base portion 2 and the fin groups 3, 4, and 5, respectively. Due to this, the heating element 61A and the like are cooled.

Here, an example of a specific method of forming the heat dissipation fin part 10 (fin groups 3, 4, and 5) will be described also with reference to FIGS. 5 and 6.

The fin groups 3, 4, and 5 are configured as so-called stacked fins by arranging a plurality of fin plates FP in the second direction. The fin plate FP is formed of a metal plate extending in the first direction, and is formed of, for example, a copper plate. Each of the fin plates FP1, FP2, and FP3 illustrated in the drawings is a type of fin plate FP. That is, FP is used as an overall reference sign of the fin plate.

FIG. 5 is a perspective view of the first fin plate FP1. The first fin plate FP1 includes fins 30, 40, and 50. The fins 30, 40, and 50 constitute the fin groups 3, 4, and 5, respectively.

As illustrated in FIG. 5, the fin 30 includes a first fin part 301, a second fin part 302, and a third fin part 303.

The first fin part 301 includes a bottom plate portion 301A, a wall part 301B, and a top plate portion 301C. The wall part 301B has a plate shape extending in the first direction and the third direction and having the second direction as the thickness direction. The bottom plate portion 301A is formed by being bent from a third direction other side end portion of the wall part 301B to the other side in the second direction. The top plate portion 301C is formed by being bent from a third direction one side end portion of the wall part 301B to the other side in the second direction. The top plate portion 301C is provided to be divided into one side in the first direction and the other side in the first direction of a notch part 3011 described later. The bottom plate portion 301A and the top plate portion 301C oppose each other in the third direction. Due to this, the first fin part 301 has a U-shaped cross section in a cross section orthogonal to the first direction.

The bottom plate portion 301A and bottom plate portions 302A and 303A described later are a part of a bottom plate portion BT extending over the entire length in the first direction of the first fin plate FP1.

The second fin part 302 is continuously provided on one side in the first direction of the first fin part 301, and includes the bottom plate portion 302A and a wall part 302B. The wall part 302B has a plate shape extending in the first direction and the third direction and having the second direction as the thickness direction. The wall part 302B is continuously provided on one side in the first direction of the wall part 301B. The position on one side end surface in the third direction of the wall part 302B is on the other side in the third direction relative to the position of one side end surface in the third direction of the wall part 301B.

The bottom plate portion 302A is formed by being bent from the third direction other side end portion of the wall part 302B to the other side in the second direction. Due to this, the second fin part 302 has an L-shaped cross section in a cross section orthogonal to the first direction.

The third fin part 303 is continuously provided on the other side in the first direction of the first fin part 301, and includes the bottom plate portion 303A and a wall part 303B. The wall part 303B has a plate shape extending in the first direction and the third direction and having the second direction as the thickness direction. The wall part 303B is continuously provided on the other side in the first direction of the wall part 301B.

The bottom plate portion 303A is formed by being bent from the third direction other side end portion of the wall part 303B to the other side in the second direction. Due to this, the third fin part 303 has an L-shaped cross section in a cross section orthogonal to the first direction. The position on one side end surface in the third direction of the wall part 303B is on the other side in the third direction relative to the position of one side end surface in the third direction of the wall part 301B on the other side in the first direction, and is at the third direction position same as the position of the one side end surface in the third direction of the wall part 301B on the one side in the first direction.

Since the fins 40 and 50 are basically configured similarly to the fin 30, detailed reference numerals are omitted in FIG. 4 for convenience. A first fin part 401 of the fin 40 includes a top plate portion 401C. The top plate portion 401C is provided to be divided into one side in the first direction and the other side in the first direction of a notch part 4011 described later. A first fin part 501 of the fin 50 includes a top plate portion 501C. The top plate portion 501C is provided to be divided into one side in the first direction and the other side in the first direction of a notch part 5011 described later.

A coupling fin 71 is disposed between the second fin part 302 and a third fin part 403. The coupling fin 71 couples the fins 30 and 40 in the first direction. A coupling fin 72 is disposed between a second fin part 402 and the third fin part 503. The coupling fin 72 couples the fins 40 and 50 in the first direction. The functions of the coupling fins 71 and 72 will be described later.

FIG. 6 is a perspective view of the second fin plate FP2. The difference in configuration between the second fin plate FP2 and the first fin plate FP1 is that only a part of the bottom plate portion BT is arranged without the coupling fin 71 being arranged between the fin 30 and the fin 40, and only a part of the bottom plate portion BT is arranged without the coupling fin 72 being arranged between the fin 40 and the fin 50.

In a second direction other side end region R2 (see FIG. 4) of the heat dissipation fin part 10, the third fin plate FP3 (see FIG. 1) is disposed closest to the other side in the second direction, and the first fin plate FP1 and the second fin plate FP2 are alternately disposed in the second direction on one side in the second direction of the third fin plate FP3. The third fin plate FP3 has a flat plate shape extending in the first direction and the third direction and having the second direction as the thickness direction. The third fin plate FP3 has a configuration in which the bottom plate portion and the top plate portion are removed from the second fin plate FP2. The third fin plate FP3 has a hole part corresponding to a through hole 80 provided at a location where a spoiler 8 (described later) is formed in the fin plates FP1 and FP2, and is not provided with a spoiler.

In the second direction other side end region R2, the fin plates FP1, FP2, and FP3 are arranged in the second direction, whereby the plurality of third fin parts 303 are arranged in the second direction at a first direction other side end portion in the second direction other side end region R2. Due to this, an end portion fin group 3A is formed (see FIG. 2).

In a second direction one side end region R1 (see FIG. 4) of the heat dissipation fin part 10, the first fin plate FP1 and the second fin plate FP2 are alternately disposed in the second direction. In the second direction one side end region R1, the fin plates FP1 and FP2 are arranged in the second direction, whereby the plurality of third fin parts 303 are arranged in the second direction at a first direction other side end portion in the second direction one side end region R1. Due to this, an end portion fin group 3B is formed (see FIG. 2).

In the region between the second direction one side end region R1 and the second direction other side end region R2, the fin plates FP not having the third fin part 303 on the other side in the first direction in the fin plates FP1 and FP2 are alternately arranged in the second direction. Due to this, 3C recessed to the other side in the third direction is formed between the end portion fin groups 3A and 3B (FIG. 2).

By checking the recessed portion 3C, the worker can suppress an error in the attachment direction when attaching the heat dissipator 1. The end portion fin group may be formed at a first direction one side end portion of the downstream side fin group 5, but is desirably provided in the upstream side fin group 3 as illustrated in FIG. 1. Due to this, by providing the recessed portion 3C on the upstream side, it is possible to reduce the flow path resistance on the second direction center side when the refrigerant W flows into the fin group 3, and improve the cooling performance of cooling the heating elements 61A and 61B positioned on the second direction center side in the fin group 3.

In this manner, the heat dissipation fin part 10 (fin groups 3, 4, and 5) is formed with various fin plates FP arranged in the second direction and integrated by, for example, caulking or the like. The formed heat dissipation fin part 10 is fixed to the one side surface 21 in the third direction of the base portion 2 by brazing, for example. In this manner, by configuring the heat dissipation fin part 10 using the fin plate FP having a configuration in which the fins 30, 40, and 50 are integrated in the first direction, it is possible to increase the rigidity of the heat dissipator 1 and suppress deflection and the like due to flow of the refrigerant W even when the thickness of the base portion 2 is reduced for thermal conductivity.

The flow of the refrigerant W in the heat dissipator 1 having such a configuration will be described with reference to FIG. 3. In FIG. 3, the flow of the refrigerant W is indicated by an arrow.

In the fin groups 3, 4, and 5, the refrigerant W flows through a flow path formed by the fins 30, 40, and 50 adjacent in the second direction. At this time, the refrigerant W flows on the bottom plate portion BT. When the fin plate FP is not provided with the bottom plate portion BT, the refrigerant W flows on the base portion 2. In the fin 30, the refrigerant W is guided along the wall surfaces (surfaces orthogonal to the second direction) of the wall parts 303B, 301B, and 302B. The refrigerant W is guided along the wall surfaces (see FIG. 5) of wall parts 403B, 401B, and 402B in the fin 40. The refrigerant W is guided along the wall surfaces (see FIG. 5) of wall parts 503B, 501B, and 502B in the fin 50.

On the other hand, the refrigerant W also flows in gaps S1A and S1B between the top plate portion 301C of the fin 30 and the top surface 100C of the liquid-cooled jacket 100.

Here, the first fin part 301 of the fin 30 is provided with the notch part 3011 notched from a third direction one side end portion to the other side in the third direction. As illustrated in FIG. 3, the notch part 3011 is disposed between the heating elements 61A and 61B in the first direction as viewed in the second direction. Since the necessity of cooling performance is low between the two heating elements 61A and 61B arranged side by side in the first direction, the notch part 3011 may be provided at that location to reduce the contact area of the fin 30 in contact with the refrigerant W. The notch part 3011 has an effect of stopping growth of a boundary layer in the fin 30 to improve the cooling performance, and an effect of mixing the refrigerant W to equalize the temperature of the refrigerant W. The boundary layer is a region formed in the vicinity of the fin by the action of viscosity at a low speed when the refrigerant W flows along the fin. The notch parts 4011 and 5011 provided in the fins 40 and 50 are also similar to the above.

In the notch part 3011, the top plate portion 301C is divided in the first direction, and an opening portion 30A open to one side in the third direction is formed between the two top plate portions 301C. A part of the refrigerant W flowing through the gap S1A on one side in the third direction of the top plate portion 301C on the other side in the first direction flows into the other side in the third direction of the top plate portion 301C on one side in the first direction via the opening portion 30A. The refrigerant W flowing through the gap S1A contributes little to cooling and has a low temperature. When the refrigerant W having such a low temperature flows into the other side in the third direction of the top plate portion 301C on one side in the first direction via the opening portion 30A, it is possible to cool the refrigerant W whose temperature has increased by cooling of the heating element 61A and to improve cooling performance for cooling the heating element 61B.

Another part of the refrigerant W flowing through the gap S1A flows through the gap S1B on one side in the third direction of the top plate portion 301C on one side in the first direction. In the fin 40, an opening portion 40A open to one side in the third direction is arranged adjacent to the other side in the first direction of the top plate portion 401C on the other side in the first direction. The opening portion 40A is provided at the first direction other side end portion of the fin 40. A part of the refrigerant W flowing through the gap S1B flows into the other side in the third direction of the top plate portion 401C on the other side in the first direction via the opening portion 40A. The refrigerant W flowing through the gap S1B contributes little to cooling and has a low temperature. When the refrigerant W having such a low temperature flows into the other side in the third direction of the top plate portion 301C on the other side in the first direction via the opening portion 40A, it is possible to cool the refrigerant W whose temperature has increased by cooling of the heating element 61B and to improve cooling performance for cooling the heating element 62A.

Another part of the refrigerant W flowing through the gap S1B flows through a gap S2A on one side in the third direction of the top plate portion 301C on the other side in the first direction. A part of the refrigerant W flowing through the gap S2A flows into the other side in the third direction of the top plate portion 401C on the other side in the first direction via the opening portion 40B formed between the two top plate portions 401C. Due to this, the refrigerant W whose temperature has increased due to the cooling of the heating element 62A can be cooled by the refrigerant W flowing in through the opening portion 40B, and the cooling performance for cooling the heating element 62B can be improved. Another part of the refrigerant W flowing through the gap S2A flows through a gap S2B on one side in the third direction of the top plate portion 401C on one side in the first direction.

Here, a height HT of the top surface 100C in the liquid-cooled jacket 100 from the base portion 2 is constant in the first direction. In the fin 30, a height H1A of the top plate portion 301C on the other side in the first direction from the base portion 2 is the same as a height H1B of the top plate portion 301C on one side in the first direction from the base portion 2. Therefore, the gap S1A and the gap S1B are the same. In the fin 40, a height H2A of the top plate portion 401C on the other side in the first direction from the base portion 2 is the same as a height H2B of the top plate portion 401C on one side in the first direction from the base portion 2. Therefore, the gap S2A and the gap S2B are the same. The heights H2A and H2B are higher than the heights H1A and H1B. Therefore, the gaps S2A and S2B are narrower than the gaps S1A and S1B.

Since the gaps S1A and S1B arranged on the upstream side are wide, the amount of the refrigerant W flowing on the other side in the third direction of the top plate portion 301C decreases, and the cooling performance in the fin 30 decreases. However, since the refrigerant W flows through the wide gaps S1A and S1B, pressure loss can be suppressed. Since the gaps S2A and S2B arranged on the downstream side are narrow, the pressure loss increases, but the amount of the refrigerant W flowing on the other side in the third direction of the top plate portion 401C increases, and thus the cooling performance is improved. Therefore, the pressure loss is suppressed without unnecessarily improving the cooling performance on the upstream side where the temperature of the refrigerant W is low and the cooling performance is relatively unnecessary, and the cooling performance is improved on the downstream side where the cooling performance is relatively necessary, whereby both improvement of the cooling performance and suppression of the pressure loss can be achieved.

In the fin 50, the opening portions 50A and 50B are provided similarly to the fin 40, and the refrigerant W flows also in the fin 50 similarly to the flow of the refrigerant W in the fin 40 described above. Since heights H3A and H3B of the top plate portion 501C of the fin 50 from the base portion 2 are the same, gaps S3A and S3B between the top plate portion 501C and the top surface 100C are the same. Since the heights H3A and H3B are higher than the heights H2A and H2B, the gaps S3A and S3B are narrower than the gaps S2A and S3B. Therefore, similarly to the effect described above, both improvement of the cooling performance and suppression of the pressure loss can be achieved.

In other words, in the above configuration, the heat dissipator 1 includes a first fin group 3 configured by arranging, in the second direction, a plurality of first fins 30 protruding from the base portion 2 to one side in the third direction. The heat dissipator 1 includes second fin groups 4 and 5 configured by arranging, in the second direction, a plurality of second fins 40 and 50 protruding from the base portion 2 to one side in the third direction, at least one of which is disposed on one side in the first direction that is the downstream side of the first fin group 3. A first top plate portion 301C is provided at a third direction one side end portion of at least any of the first fins 30. Second top plate portions 401C and 501C are provided at a third direction one side end portion of at least any of the second fins 40 and 50. At least any of the second fins 40 and 50 has the opening portions 40A, 40B, 50A, and 50B that are open to the one side in the third direction and are arranged on the other side in the first direction relative to the second top plate portions 401C and 501C. The liquid-cooled jacket 100 includes the top surface 100C that can oppose the first top plate portion 301C and the second top plate portions 401C and 501C in the third direction. The first gaps S1A and S1B between the top surface 100C and the first top plate portion 301C and the second gaps S2A, S2B, S3A, and S3B between the top surface 100C and the second top plate portions 401C and 501C are narrower toward the one side in the first direction (S1A, S1B>S2A, S2B>S3A, S3B).

As illustrated in FIG. 4, when viewed in the third direction, the first gaps S1A and S1B overlap the first heating elements 61A and 61B, and the second gaps S2A, S2B, S3A, and S3B overlap the second heating elements 62A, 62B, 63A, and 63B. This makes it possible to suppress a temperature difference between the first heating element and the second heating element.

The second fins 40 and 50 have the first direction other side end portion adjacent to the other side in the first direction of the second top plate portions 401C and 501C. The opening portions 40A and 50A are provided at the first direction other side end portion. Due to this, the refrigerant W can flow into the second fins 40 and 50 at the most upstream side location in the second fins 40 and 50, and therefore the cooling performance in the second fins 40 and 50 can be improved.

The heights H1A and H1B of the first top plate portion 301C from the base portion 2 and the heights H2A, H2B, H3A, and H3B of the second top plate portions 401C and 501C from the base portion 2 are higher toward one side in the first direction. Due to this, when the height HT of the top surface 100C of the liquid-cooled jacket 100 from the base portion 2 is constant, the second gaps S2A and S2B can be made narrower than the first gaps S1A and S1B, and the second gaps S3A and S3B can be made narrower than the second gaps S2A and S2B.

The gaps S1A and S1B, the gaps S2A and S2B, and the gaps S3A and S3B may be different from each other. In this case, for example, S1A>S1B>S2A>S2B>S3A>S3B.

The notch parts 3011, 4011, and 5011 and the opening portions 30A, 40B, and 50B are not necessarily provided.

The number of fin groups is not limited to three (3, 4, 5) as in the above example embodiment, and may be two or four or more.

As illustrated in FIGS. 5 and 6, the first fin plate FP1 and the second fin plate FP2 are provided with the spoiler 8. Here, the spoiler 8 will be described in detail.

As illustrated in FIG. 5, in the first fin plate FP1, the fins 30, 40, and 50 are each provided with the spoiler 8. As illustrated in FIG. 6, also in the second fin plate FP2, the spoiler 8 is provided similarly to the first fin plate FP1. In FIG. 6, detailed reference numerals of the configuration of the spoiler 8 are omitted for convenience.

As illustrated in FIG. 5, the spoiler 8 includes a first spoilers 811 and 812 and a second spoiler 82. The first spoilers 811 and 812 are the spoiler 8 (single spoiler) provided with only any one of spoilers 8A and 8B described later. The second spoiler 82 is the spoiler 8 (double spoiler) provided with both of the spoilers 8A and 8B described later. In the example illustrated in FIG. 5, the first spoiler 811 is provided on the fins 30 and 40, the first spoiler 812 is provided on the fin 30, and the second spoiler 82 is provided on the fins 40 and 50.

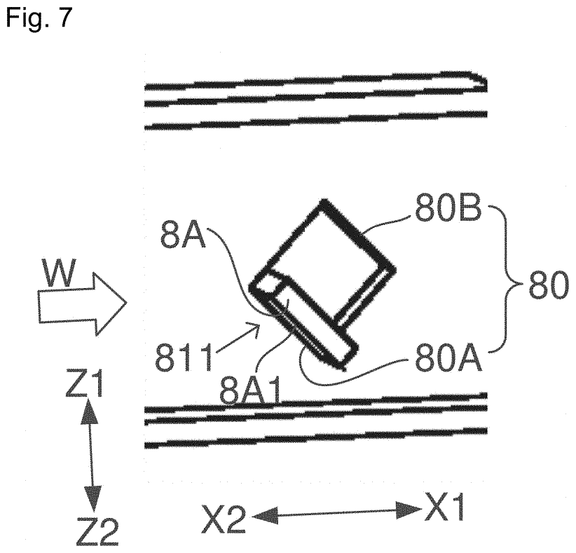

FIG. 7 is an enlarged perspective view illustrating the configuration of the first spoiler 811. The first spoiler 811 includes only the spoiler 8A. The through hole 80 penetrates the wall part of the fins 30 and 40 in the second direction. The through hole 80 has a rectangular shape. The through hole 80 has a pair of opposing sides 80A and 80B inclined on one side in the first direction and the other side in the third direction. The side 80A is positioned on the other side in the first direction relative to the side 80B. The spoiler 8A is formed by being bent on the other side in the second direction on the side 80A. The through hole 80 and the spoiler 8A can be formed by making a cut in the wall part and bending the wall part.

The spoiler 8A includes an opposing surface 8A1 opposing the direction in which the refrigerant W flows, that is, one side in the first direction. The first spoiler 811 includes a function of interrupting the flow of the refrigerant W by the opposing surface 8A1. Turbulence of the refrigerant W is easily generated in the vicinity of the opposing surface 8A1, and the cooling performance by the fins 30 and 40 can be improved. The spoiler 8A is inclined to one side in the first direction and the other side in the third direction. Due to this, the refrigerant W can be guided to the heating element side by the spoiler 8A, and the cooling performance can be improved.

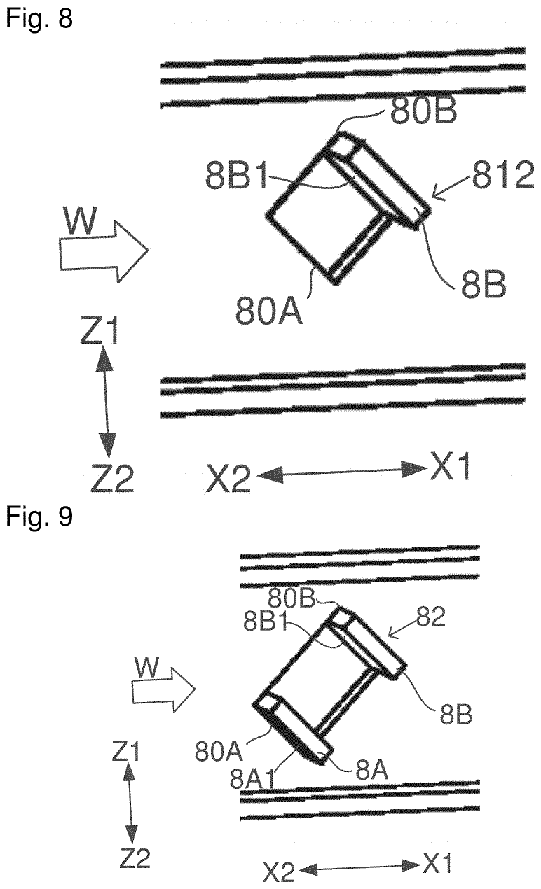

FIG. 8 is an enlarged perspective view illustrating the configuration of the first spoiler 812. The first spoiler 812 includes only the spoiler 8B. The spoiler 8B is formed by being bent on the other side in the second direction on the side 80B of the through hole 80. The through hole 80 and the spoiler 8B can be formed by making a cut in the wall part and bending the wall part.

The spoiler 8B includes an opposing surface 8B1 opposing the direction in which the refrigerant W flows, that is, one side in the first direction. The first spoiler 812 includes a function of interrupting the flow of the refrigerant W by the opposing surface 8B1. Turbulence of the refrigerant W is easily generated in the vicinity of the opposing surface 8B1, and the cooling performance by the fins 30 can be improved. The spoiler 8B is inclined to one side in the first direction and the other side in the third direction. Due to this, the refrigerant W can be guided to the heating element side by the spoiler 8B, and the cooling performance can be improved.

FIG. 9 is an enlarged perspective view illustrating the configuration of the second spoiler 82. The second spoiler 82 includes the spoilers 8A and 8B. The second spoiler 82 includes a function of interrupting the flow of the refrigerant W by the opposing surfaces 8A1 and 8B1 of the spoilers 8A and 8B. Turbulence of the refrigerant W is easily generated in the vicinity of the opposing surfaces 8A1 and 8B1, and the cooling performance by the fins 40 and 50 can be improved. The second spoiler 82 is a larger than the first spoilers 811 and 812 in the number of spoilers, and thus has high cooling performance.

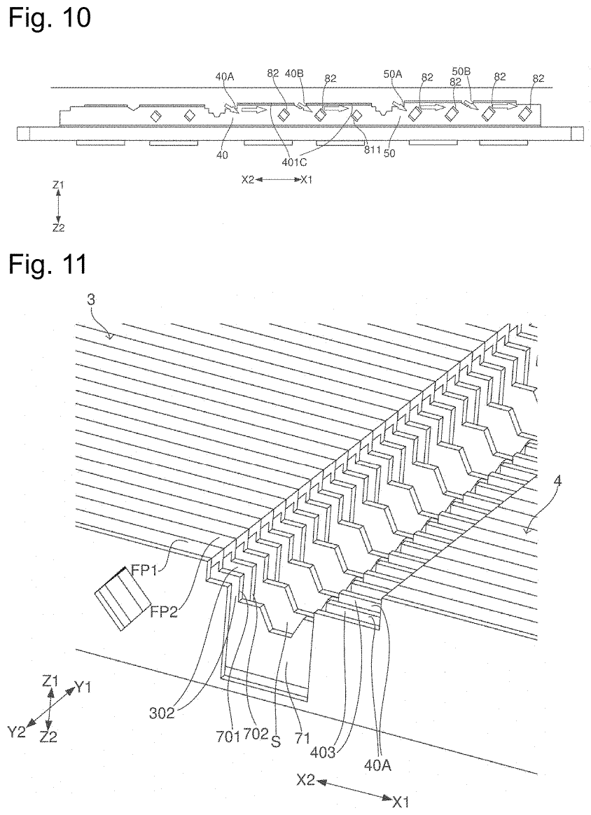

Here, as indicated by the arrow indicating the flow of the refrigerant W in FIG. 10, the refrigerant W flowing into the fin 40 via the opening portions 40A and 40B easily flows on one side in the third direction inside the fin 40. Similarly, the refrigerant W flowing into the fin 50 through the opening portions 50A and 50B easily flows on one side in the third direction inside the fin 50. Therefore, the fin 40 is provided with the second spoiler 82 and the first spoiler 811. By generating turbulence by the second spoiler 82 on the other side in the first direction, the refrigerant W heated inside the fin 30 and flowing into the fin 40 and the refrigerant W flowing into the fin 40 through the opening portion 40A are exchanged and mixed to improve the cooling performance. By generating turbulence by the second spoiler 82 and the first spoiler 811 on one side in the first direction, the refrigerant W heated on the other side in the third direction of the top plate portion 401C on the other side in the first direction and flowing into the other side in the third direction of the top plate portion 401C on one side in the first direction and the refrigerant W flowing into the fin 40 through the opening portion 40B are exchanged and mixed to improve the cooling performance.

By providing the second spoiler 82 also for the refrigerant W flowing into the fin 50 through the opening portions 50A and 50B, the refrigerant W is exchanged and mixed inside the fin 50 similarly to the above to improve the cooling performance.

That is, at least any of the second fins 40 and 50 has at least one spoiler 8 protruding in the second direction from the side surface of the second fins 40 and 50. Due to this, by causing the spoiler 8 to generate turbulence, and exchanging and mixing, in the third direction of the refrigerant W, the refrigerant W flowing into the second fins 40 and 50 through the opening portions 40A, 40B, 50A, and 50B, it is possible to improve the cooling performance in the second fins 40 and 50.

As illustrated in FIG. 10, the fin 40 is provided with the two second spoilers 82 and the one first spoiler 811, and provided with the total of the five spoilers 8. The fin 50 is provided with the four second spoilers 82, and provided with the total of the eight spoilers 8.

That is, the number of the spoilers 8 included in each of the plurality of second fins 40 and 50 arranged in the first direction increases toward the one side in the first direction. Due to this, it is possible to improve the cooling performance by exchanging and mixing more the refrigerant W in the second fin 50 on the downstream side where more cooling performance is necessary.

Next, the configuration among each of the fins 30, 40, and 50 will be described in more detail. Here, the configuration between the fin 30 and the fin 40 will be described as an example with reference to FIG. 11, but the content of the configuration between the fin 40 and the fin 50 is similar.

FIG. 11 is a partially enlarged view illustrating the configuration in the vicinity between the upstream side fin group 3 and the center fin group 4. As illustrated in FIG. 11, a plurality of the second fin parts 302 of the fin plates FP1 and FP2 are arranged in the second direction. A plurality of the third fin parts 403 of the fin plates FP1 and FP2 are arranged in the second direction.

As illustrated in FIG. 11, in the first fin plate FP1, the coupling fin 71 is formed between the second fin part 302 and the third fin part 403, and a recessed portion 701 recessed to the other side in the third direction is formed on one side in the third direction of the coupling fin 71. In the second fin plate FP2, a coupling fin is not formed between the second fin part 302 and the third fin part 403, and a recessed portion 702 is formed. The recessed portion 702 is recessed to the other side in the third direction up to the base portion 2. The recessed portions 701 and 702 and the opening portion 40A formed as described above form an open slot S. The open slot S has an effect of stopping growth of a boundary layer in the fin to improve the cooling performance, an effect of mixing the refrigerant W discharged from the downstream side outlet of the fin group 3, and an effect of reducing the pressure loss. By providing the coupling fin 71, it is possible to improve rigidity of the heat dissipator 1, increase the contact area with the refrigerant W in the open slot S to improve the cooling performance.

In other words, in the configuration illustrated in FIG. 11, the recessed portions 701 and 702 recessed to the other side in the third direction are provided between the first direction other side end portion of at least any of the second fins 40 and the first direction one side end portion of the first fin 30. Due to this, the refrigerant W can be easily guided to the base portion 2 side between the first fin 30 and the second fin 40, and the cooling performance in the second fin 40 on the downstream side can be improved.

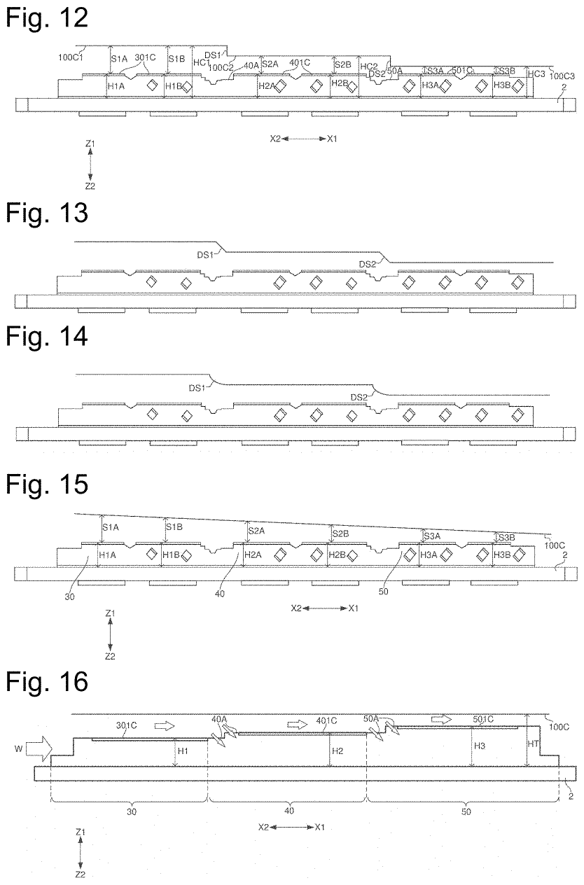

FIG. 12 is a side view of the heat dissipator 1 according to the first modification as viewed to one side in the second direction. FIG. 12 is a view corresponding to FIG. 3 described above.

As illustrated in FIG. 12, the height H1A of the top plate portion 301C on the other side in the first direction from the base portion 2, the height H1B of the top plate portion 301C on one side in the first direction from the base portion 2, the height H2A of the top plate portion 401C on the other side in the first direction from the base portion 2, the height H2B of the top plate portion 401C on one side in the first direction from the base portion 2, the height H3A of the top plate portion 501C on the other side in the first direction from the base portion 2, and the height H3B of the top plate portion 501C on one side in the first direction from the base portion 2 are the same.

The top surface 100C of the liquid-cooled jacket 100 includes an opposing surface 100C1 that opposes the top plate portion 301C in the third direction, an opposing surface 100C2 that opposes the top plate portion 401C in the third direction, and an opposing surface 100C3 that can oppose the top plate portion 501C in the third direction. A height HC2 of the opposing surface 100C2 from the base portion 2 is lower than a height HC1 of the opposing surface 100C1 from the base portion 2. A height HC3 of the opposing surface 100C3 from the base portion 2 is lower than the height HC2 of the opposing surface 100C2 from the base portion 2. That is, HC1>HC2>HC3.

In other words, the top surface 100C includes a first opposing surface 100C1 that can oppose the first top plate portion 301C and the third direction, and second opposing surfaces 100C2 and 100C3 that can oppose the second top plate portions 401C and 501C and the third direction. The height HC1 of the first opposing surface 100C1 from the base portion 2 and the heights HC2 and HC3 of the second opposing surface 100C2 and 100C3 from the base portion 2 are lower toward the one side in the first direction.

Due to this, the gap S1A=S1B, the gap S2A=S2B, the gap S3A=S3B, and S1A, S1B>S2A, S2B>S3A, S3B are established. Therefore, similarly to the above-described example embodiment, both improvement of the cooling performance and suppression of the pressure loss can be achieved.

As illustrated in FIG. 12, a step DS1, which is a plane extending perpendicular to the first direction, is formed at the boundary between the opposing surfaces 100C1 and 100C2. In FIG. 12, as viewed in the second direction, the step DS1 is positioned at an intermediate position in the first direction of the opening portion 40A. Similarly, a step DS2, which is a plane extending perpendicular to the first direction, is formed at the boundary between the opposing surfaces 100C2 and 100C3. In FIG. 12, as viewed in the second direction, the step DS2 is positioned at an intermediate position in the first direction of the opening portion 50A. For example, the steps DS1 and DS2 may be positioned at the positions of the other side ends in the first direction of the opening portions 40A and 50A.

That is, at least a part of the opening portion 40A is disposed on one side in the first direction relative to the step DS1 provided at the boundary between the first opposing surface 100C1 and the second opposing surface 100C2. This facilitates the refrigerant W flowing through the first gap S1B to easily flow into the opening portion 40A.

FIG. 13 is a side view of the heat dissipator 1 according to the second modification as viewed to one side in the second direction. FIG. 13 is a view corresponding to FIG. 3 described above.

The present modification is a modification of the first modification, and the steps DS1 and DS2 are formed by inclined surfaces.

FIG. 14 is a side view of the heat dissipator 1 according to the third modification as viewed to one side in the second direction. FIG. 14 is a view corresponding to FIG. 3 described above.

The present modification is a modification of the first modification, and the steps DS1 and DS2 are formed by curved surfaces.

FIG. 15 is a side view of the heat dissipator 1 according to the fourth modification as viewed to one side in the second direction. FIG. 15 is a view corresponding to FIG. 3 described above.

In the present modification, as illustrated in FIG. 15, the top surface 100C is an inclined surface that is continuously inclined across the fins 30, 40, and 50. The top surface 100C is inclined to one side in the first direction and the other side in the third direction.

The heights H1A, H1B, H2A, H2B, H3A, and H3B of the respective top plate portions from the base portion 2 are the same. Due to this, regarding the gap between each top plate portion and the top surface 100C, S1A>S1B>S2A>S2B>S3A>S3B is established. Also according to such example embodiment, both improvement of the cooling performance and suppression of the pressure loss can be achieved.

FIG. 16 is a side view of the heat dissipator 1 according to the fifth modification as viewed to one side in the second direction. FIG. 16 is a view corresponding to FIG. 3 described above.

In the present modification, as illustrated in FIG. 16, the fins 30, 40, and 50 are continuously provided in the first direction. The opening portion 40A of the fin 40 is provided between the top plate portion 301C of the fin 30 and the top plate portion 401C of the fin 40. The opening portion 40A is disposed at the first direction other side end portion of the fin 40. The opening portion 50A of the fin 50 is provided between the top plate portion 401C of the fin 40 and the top plate portion 501C of the fin 50. The opening portion 50A is disposed at the first direction other side end portion of the fin 50.

Thus, in the present modification, the open slot is simplified without providing a recessed portion such as the recessed portions 701 and 702 between the fins as in the above-described example embodiment (see FIG. 11). In the configuration illustrated in FIG. 16, the heights H1, H2, and H3 of the top plate portions 301C, 401C, and 501C from the base portion 2 are in a relationship of H1<H2<H3, and the height HT of the top surface 100C of the liquid-cooled jacket 100 from the base portion 2 is constant in the first direction. However, the configuration with the simplified open slot may be applied to a configuration in which the height of the top surface 100C from the base portion 2 changes in the first direction as in the second modification.

The example embodiment of the present disclosure has been described above. The scope of the present disclosure is not limited to the above example embodiment. The present disclosure can be implemented by making various changes to the above example embodiment without departing from the gist of the disclosure. The above example embodiment describes matters that can be optionally combined together, as appropriate, as long as there is no inconsistency.

For example, the fin group is not limited to stacked fins, and a plurality of fin columns in which a plurality of pin fins protruding in a columnar shape from the base portion 2 on one side in the third direction are arranged in the first direction may be arranged in the second direction. In this case, the top plate portion is provided at a third direction one side end portion of the fin column.

For example, a vapor chamber or a heat pipe may be provided between the heating element and the heat dissipator.

The present disclosure can be used for cooling of various heating elements.

Features of the above-described example embodiments and the modifications thereof may be combined appropriately as long as no conflict arises.

While example embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A heat dissipator that can be installed in a liquid-cooled jacket, the heat dissipator comprising:
a plate-shaped base expanding in a first direction along a refrigerant flow direction and in a second direction orthogonal to the first direction, and having a thickness in a third direction orthogonal to the first direction and the second direction;
a first fin group including first fins arranged in the second direction and protruding from the base to one side in the third direction; and
a second fin group including second fins arranged in the second direction and protruding from the base to the one side in the third direction, at least one of the second fins being located on one side in the first direction that is a downstream side of the first fin group; wherein
a first top plate is provided at a third direction one side end of at least any of the first fins;
a second top plate is provided at a third direction one side end of at least any of the second fins;
the at least any of the second fins includes an opening that is open to the one side in the third direction and is located on another side in the first direction relative to the second top plate;
the liquid-cooled jacket includes a top surface that is able to oppose the first top plate and the second top plate in the third direction; and
a first gap between the top surface and the first top plate and a second gap between the top surface and the second top plate are narrower toward the one side in the first direction.

2. The heat dissipator according to claim 1, wherein
each of the second fins includes a first direction other side end adjacent to the other side in the first direction of the second top plate; and
the opening is located at the first direction other side end.

3. The heat dissipator according to claim 2, wherein a recess is recessed to another side in the third direction and located between at least any of the first direction other side ends and a first direction one side end of the first fin.

4. The heat dissipator according to claim 1, wherein at least any of the second fins includes at least one spoiler protruding in the second direction from a side surface of the second fin.

5. The heat dissipator according to claim 4, wherein a number of the spoilers included in each of the second fins arranged in the first direction increases toward the one side in the first direction.

6. The heat dissipator according to claim 1, wherein a height of the first top plate from the base and a height of the second top plate from the base are higher toward one side in the first direction.

7. The heat dissipator according to claim 1, wherein
the top surface includes a first opposing surface that can oppose the first top plate and the third direction, and a second opposing surface that can oppose the second top plate and the third direction; and
a height of the first opposing surface from the base and a height of the second opposing surface from the base are lower toward the one side in the first direction.

8. The heat dissipator according to claim 7, wherein at least a portion of the opening is located on the one side in the first direction relative to a step provided at a boundary between the first opposing surface and the second opposing surface.

9. The heat dissipator according to claim 1, wherein, when viewed in the third direction, the first gap and a first heating element overlap, and the second gap and a second heating element overlap.

10. A cooling device comprising:
the heat dissipator according to claim 1; and
a liquid-cooled jacket that houses the heat dissipator.
